(19) United States
(12) Patent Application Publication
(10) Pub. No.: US 2026/0040485 A1
(43) Pub. Date: Feb. 5, 2026

(54) Heat Dissipation Assembly, Connector Assembly and Shielding Shell

(71) Applicants: TE Connectivity Solutions GmbH, Schaffhausen (CH); Tyco Electronics (Shanghai) Co., Ltd., Shanghai (CN)

(72) Inventors: WenYu (Vindy) Liu, Shanghai (CN); Guangming (Suny) Zhao, Shanghai (CN); Haw Jer Shyu, Middletown, PA (US); Yang (Eric) Shi, Shanghai (CN)

(73) Assignees: TE Connectivity Solutions GmbH, Schaffhausen (CH); Tyco Electronics (Shanghai) Co., Ltd., Shanghai (CH)

(21) Appl. No.: 19/284,783

(22) Filed: Jul. 30, 2025

(30) Foreign Application Priority Data
Jul. 30, 2024 (CN) 202411036894.X

(51) Int. Cl. H05K 7/20; H01R 12/71; H01R 13/6581; H01R 13/6595

(52) U.S. Cl. CPC H05K 7/20254; H01R 12/716; H01R 13/6581; H01R 13/6595; H05K 7/20409

(57) ABSTRACT

A heat dissipation assembly includes a liquid-cooling module including a liquid-cooling plate, a bottom surface of the liquid-cooling plate has a locking structure, and an air-cooling module including a plurality of heat dissipation fins. A top surface of each of the plurality of heat dissipation fins is welded to the bottom surface of the liquid-cooling plate. The locking structure engages a locking spring piece on a side wall of a shielding shell of a connector to lock the heat dissipation assembly to the shielding shell. When the heat dissipation assembly is locked onto the shielding shell, a bottom of the air-cooling module protrudes into the shielding shell through an opening in a top wall of the shielding shell to make thermal contact with a mating connector inserted into the shielding shell.

### CROSS-REFERENCE TO RELATED APPLICATION

This application claims the benefit of the filing date under 35 U.S.C. § 119(a)-(d) of Chinese Patent Application No. 202411036894.X, filed on Jul. 30, 2024.

### FIELD OF THE INVENTION

The present invention relates to a heat dissipation assembly, a shielding shell, and a connector assembly comprising the heat dissipation assembly and the shielding shell.

### BACKGROUND OF THE INVENTION

A connector typically includes a shielding shell (also known as an iron cage) and a terminal module arranged in the shielding shell. To cool down the connector, it is usually necessary to install a heat dissipation device on the top of the shielding shell. The heat dissipation device usually includes an air-cooling module and a liquid cooled module. The air-cooling module is installed on the top wall of the shielding shell, and the liquid cooled module is installed on the top of the air-cooling module and in thermal contact with it. The air-cooling module and the liquid cooled module are separated from each other and in thermal contact with each other through pressure, which results in a high thermal resistance between the two and affects the heat dissipation performance of the connector.

In addition, the shielding shell suitable for the liquid-cooling module cannot be applied to an air-cooling heat sink with an elastic clip, which limits the application scope of the shielding shell. When it is necessary to use the air-cooling heat sink with the elastic clip, the shielding shell must be replaced, which is inconvenient in actual use.

### SUMMARY OF THE INVENTION

A heat dissipation assembly includes a liquid-cooling module including a liquid-cooling plate, a bottom surface of the liquid-cooling plate has a locking structure, and an air-cooling module including a plurality of heat dissipation fins. A top surface of each of the plurality of heat dissipation fins is welded to the bottom surface of the liquid-cooling plate. The locking structure engages a locking spring piece on a side wall of a shielding shell of a connector to lock the heat dissipation assembly to the shielding shell. When the heat dissipation assembly is locked onto the shielding shell, a bottom of the air-cooling module protrudes into the shielding shell through an opening in a top wall of the shielding shell to make thermal contact with a mating connector inserted into the shielding shell.

### BRIEF DESCRIPTION OF THE DRAWINGS

Features of the present invention will become more apparent by describing in detail exemplary embodiments thereof with reference to the accompanying drawings, in which:

FIG. 1 shows an illustrative perspective view of a connector assembly according to an exemplary embodiment of the present invention when viewed from the front side;

FIG. 2 shows an illustrative perspective view of a connector assembly according to an exemplary embodiment of the present invention when viewed from the rear side;

FIG. 3 shows an illustrative exploded view of a connector assembly according to an exemplary embodiment of the present invention when viewed from the rear side;

FIG. 4 shows an illustrative perspective view of a heat dissipation assembly according to an exemplary embodiment of the present invention when viewed from the bottom;

FIG. 5 shows an illustrative exploded view of a heat dissipation assembly according to an exemplary embodiment of the present invention when viewed from the bottom;

FIG. 6 shows an illustrative exploded view of a heat dissipation assembly according to an exemplary embodiment of the present invention when viewed from the top;

FIG. 7 shows an illustrative perspective view of a heat dissipation assembly and a shielding shell according to an exemplary embodiment of the present invention;

FIG. 8 shows an illustrative perspective view of a shielding shell according to an exemplary embodiment of the present invention;

FIG. 9 shows an illustrative perspective view of a connector assembly according to an exemplary embodiment of the present invention when viewed from the rear, with the limit plate removed and the heat dissipation assembly in a predetermined installation position;

FIG. 10 shows an illustrative perspective view of a connector assembly according to an exemplary embodiment of the present invention when viewed from the rear, wherein the heat dissipation assembly is moved forward from the installation position shown in FIG. 9 to the disassembly position;

FIG. 11 shows an illustrative perspective view of a connector assembly according to another exemplary embodiment of the present invention; and

FIG. 12 shows an illustrative exploded view of a connector assembly according to another exemplary embodiment of the present invention.

### DETAILED DESCRIPTION

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

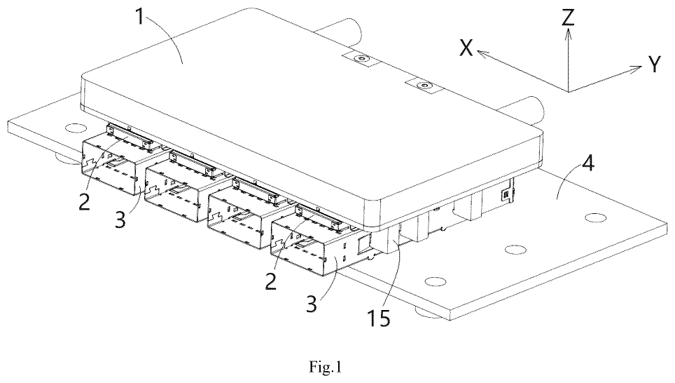

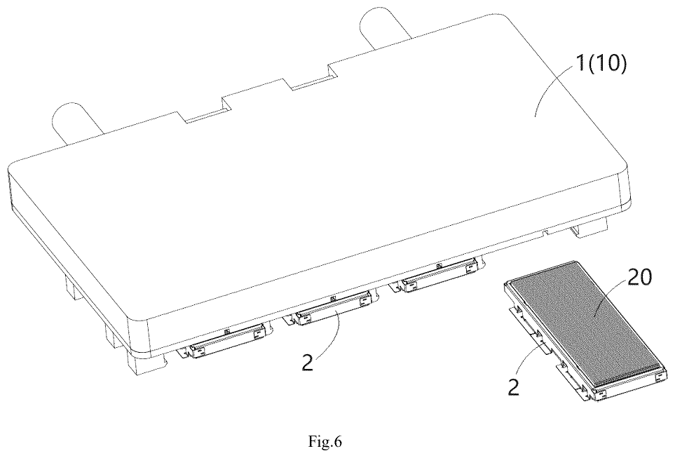

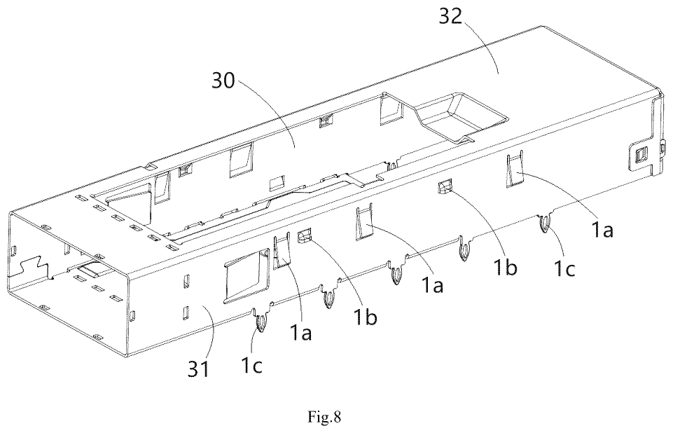

As shown in FIGS. 1 to 10, in an exemplary embodiment of the present invention, a heat dissipation assembly 100 is disclosed. The heat dissipation assembly 100 includes a liquid-cooling module 1 and an air-cooling module 2. The liquid-cooling module 1 includes a liquid-cooling plate 10. The air-cooling module 2 includes heat dissipation fins 20. The top surfaces of the heat dissipation fins 20 are welded to the bottom surface of the liquid-cooling plate 10, and a locking structure 15 is formed on the bottom surface of the liquid-cooling plate 10. The locking structure 15 is suitable for engaging with a locking spring piece 3a on a side wall 31 of a shielding shell 3 of a connector to lock the heat dissipation assembly 100 to the shielding shell 3.

In the illustrated embodiment, when the heat dissipation assembly 100 is locked onto the shielding shell 3, the bottom of the air-cooling module 2 protrudes into the shielding shell 3 through an opening 30 in the top wall 32 of the shielding shell 3 to make thermal contact with a mating connector inserted into the shielding shell 3.

As shown in FIGS. 1 to 10, in the illustrated embodiment, a cooling chamber or cooling passage is formed in the liquid-cooling plate 10 to allow the cooling liquid to flow through, and the liquid-cooling plate 10 has a cooling liquid inlet 11 and a cooling liquid outlet 12 communicated with the cooling chamber or cooling passage.

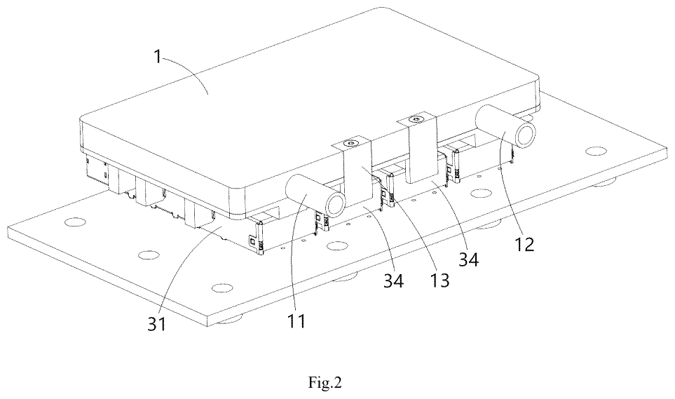

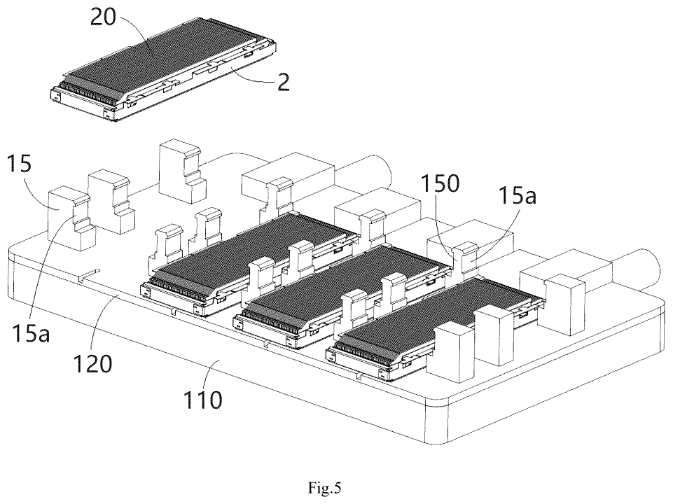

As shown in FIG. 5, in the illustrated embodiment, the liquid-cooling plate 10 includes a housing 110 and a bottom cover 120. A cooling chamber or cooling passage for accommodating cooling liquid is formed in the housing 110, and a cooling liquid inlet 11 and a cooling liquid outlet 12 communicated with the cooling chamber or cooling passage are also formed on the rear side of the housing 110, as shown in FIG. 2. The bottom cover 120 covers the bottom of the housing 110 and is used to close the bottom opening of the housing 110. The locking structure 15 is integrally formed on the bottom surface of the bottom cover 120. In the illustrated embodiment, the liquid-cooling plate 10 includes two separate components, which can reduce manufacturing costs. However, the liquid-cooling plate 10 can also be a single piece.

As shown in FIGS. 1 to 10, in the illustrated embodiment, the heat dissipation assembly 100 includes a single liquid-cooling module 1 and multiple air-cooling modules 2, which are arranged side by side and spaced apart from each other in the transverse direction X of the liquid-cooling plate 10. When the heat dissipation assembly 100 is locked onto the shielding shell 3, the bottoms of multiple air-cooling modules 2 protrude into the shielding shells 3 of multiple connectors to make thermal contact with the inserted multiple mating connectors.

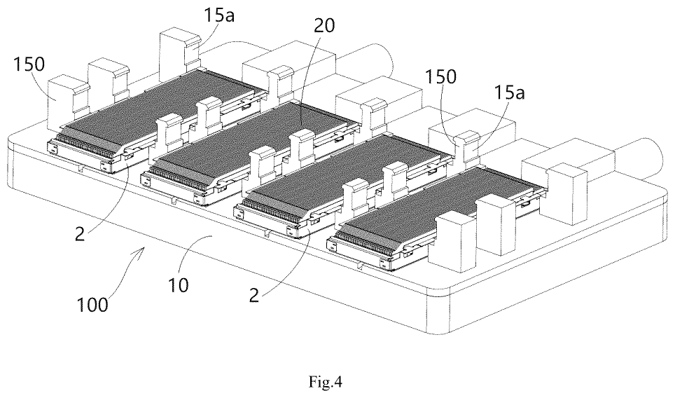

As shown in FIGS. 4 and 5, in the illustrated embodiment, the locking structure 15 on the bottom surface of the liquid-cooling plate 10 includes multiple columns of locking posts 150 arranged side by side in the transverse direction X of the liquid-cooling plate 10, each column of locking posts 150 including multiple locking posts 150 spaced apart in the longitudinal direction Y of the liquid-cooling plate 10. A snap slot 15a is formed on the side of each locking post 150, which is suitable for engaging with the locking spring piece 3a on the side wall 31 of the shielding shell 3, and adjacent columns of locking posts 150 are used to engage with two side walls 31 of the corresponding shielding shell 3, respectively.

As shown in FIGS. 4 and 5, in the illustrated embodiment, the air-cooling module 2 includes multiple heat dissipation fins 20, which are stacked together. The top surfaces of the multiple heat dissipation fins 20 are welded to the bottom surface of the liquid-cooling plate 10, and the bottom surfaces of the multiple heat dissipation fins 20 are used to protrude into the shielding shell 3 for thermal contact with the inserted mating connector. In the illustrated embodiment, the top surfaces of the heat dissipation fins 20 of the air-cooling module 2 are welded to the bottom surface of the liquid-cooling plate 10 by soldering or ultrasonic welding.

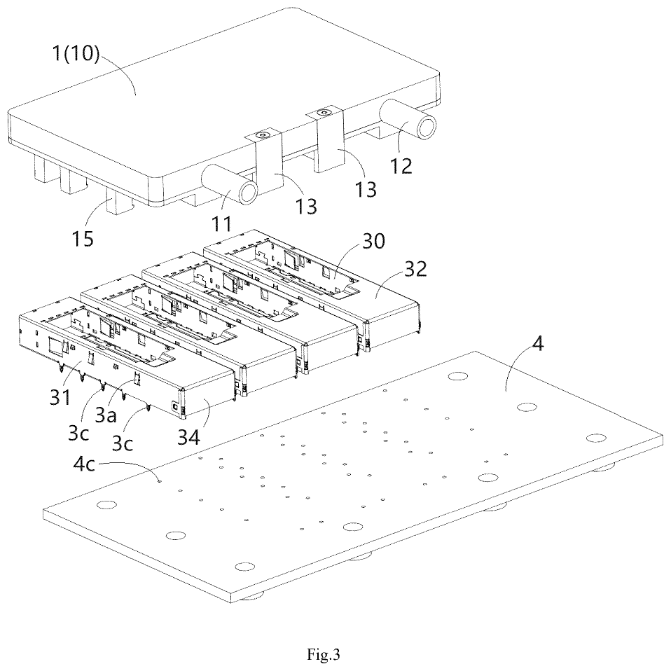

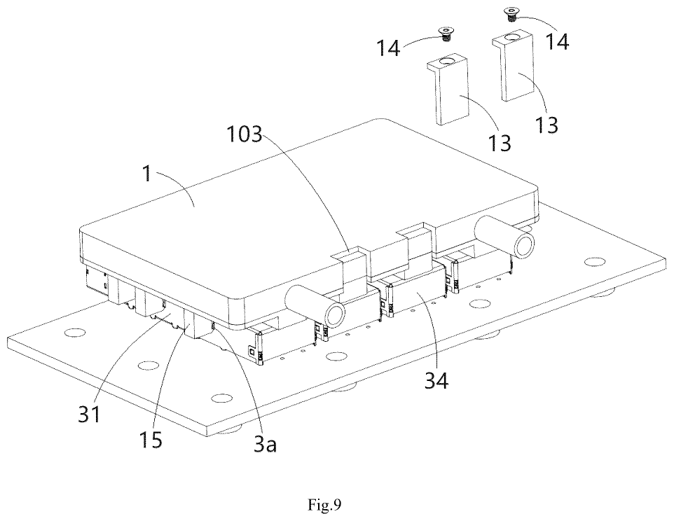

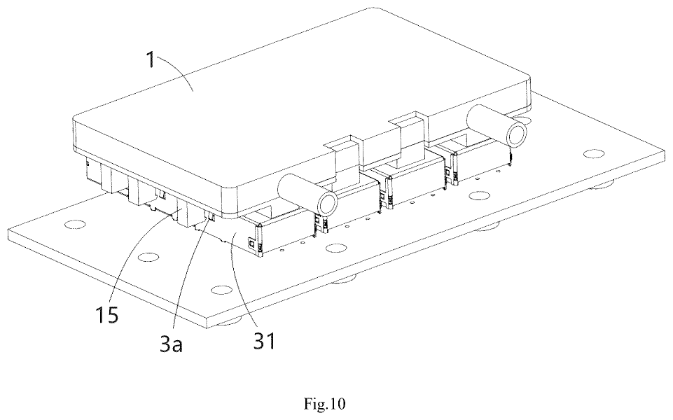

In the illustrated embodiment, the liquid-cooling plate 10 has front and rear sides that are opposite in its longitudinal direction Y. The heat dissipation assembly 100 also includes a limit plate 13, which is detachably installed on the rear side of the liquid-cooling plate 10, as shown in FIGS. 2 and 3. The limit plate 13 is suitable for pressing against the rear end wall 34 of the shielding shell 3 along the longitudinal direction Y, as shown in FIGS. 9 and 10, to restrict the heat dissipation assembly 100 in a predetermined installation position. When the heat dissipation assembly 100 is in the installation position, the locking structure 15 on the heat dissipation assembly 100 engages with the locking spring piece 3a on the shielding shell 3, so that the heat dissipation assembly 100 is locked to the shielding shell 3.

When the limit plate 13 is removed from the liquid-cooling plate 10, the heat dissipation assembly 100 can be moved forward along the longitudinal direction Y relative to the shielding shell 3 from the installation position (position shown in FIG. 9) to a disassembly position (position shown in FIG. 10). When the heat dissipation assembly 100 is in the disassembly position, the locking structure 15 on the heat dissipation assembly 100 is separated from the locking spring piece 3a on the shielding shell 3, allowing the heat dissipation assembly 100 to be removed from the shielding shell 3.

As shown in FIG. 9, in the illustrated embodiment, a positioning groove 103 is formed on the rear side of the liquid-cooling plate 10, and the upper part of the limit plate 13 is positioned in the positioning groove 103 and detachably fastened to the rear side of the liquid-cooling plate 10 by screws 14, as shown in FIG. 10.

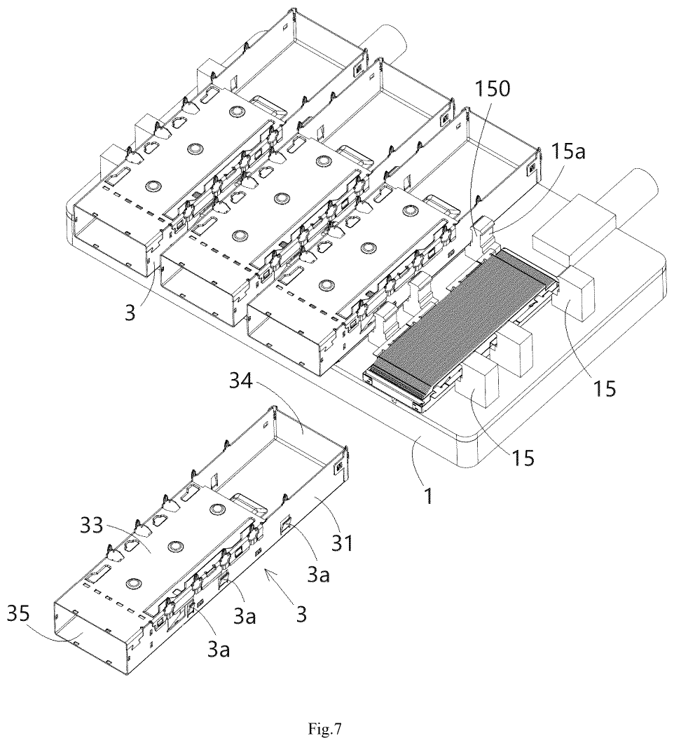

In another exemplary embodiment of the present invention, a connector assembly is also disclosed. The connector assembly includes a connector and a heat dissipation assembly 100. The connector includes a shielding shell 3, which has a top wall 32 and a bottom wall 33 that are opposite in its height direction Z, a front port 35 and a rear wall 34 that are opposite in the longitudinal direction Y, and a pair of side walls 31 that are opposite in its transverse direction X. The heat dissipation assembly 100 is installed on the top of the shielding shell 3. An opening 30 is formed in the top wall 32 of the shielding shell 3, and the bottom of the air-cooling module 2 protrudes into the shielding shell 3 through the opening 30 in the top wall 32 to make thermal contact with the mating connector inserted into the shielding shell 3. Locking spring pieces 3a are respectively formed on the pair of side walls 31 of the shielding shell 3, as shown in FIG. 7, and the locking spring pieces 3a are engaged with the locking structure 15 on the liquid-cooling plate 10 to lock the heat dissipation assembly 100 to the shielding shell 3.

As shown in FIGS. 4 and 5, in the illustrated embodiment, the heat dissipation assembly 100 includes a single liquid-cooling module 1 and multiple air-cooling modules 2, which are arranged side by side and spaced apart from each other in the transverse direction X of the liquid-cooling plate 10. The connector assembly includes multiple connectors, which are arranged side by side and spaced apart from each other in the transverse direction X of the liquid-cooling plate 10. The bottoms of multiple air-cooling modules 2 respectively protrude into the shielding shells 3 of the multiple connectors to make thermal contact with the inserted multiple mating connectors.

As shown in FIG. 3, in the illustrated embodiment, multiple plug pins 3c are formed on the lower sides of the pair of side walls 31 of the shielding shell 3, respectively. The multiple plug pins 3c are suitable for press fitting into the holes 4c in the circuit board 4 to fix the shielding shell 3 to the circuit board 4.

The connector further comprises a terminal holder and terminals. The terminal holder is installed in the shielding shell 3. The terminals are held in the terminal holder. One end of the terminal is in electrical contact with a mating terminal of the mating connector inserted from the front port 35 of the shielding shell 3, and the other end of the terminal is exposed from the bottom of the shielding shell 3 for electrical connection to the circuit board 4.

As shown in FIG. 3, in the illustrated embodiment, the connector assembly further comprises a circuit board 4, and a hole 4c is formed in the circuit board 4 to mate with the plug pin 3c on the shielding shell 3. The shielding shell 3 is fixed to the circuit board 4, and the terminals are electrically connected to the circuit board 4.

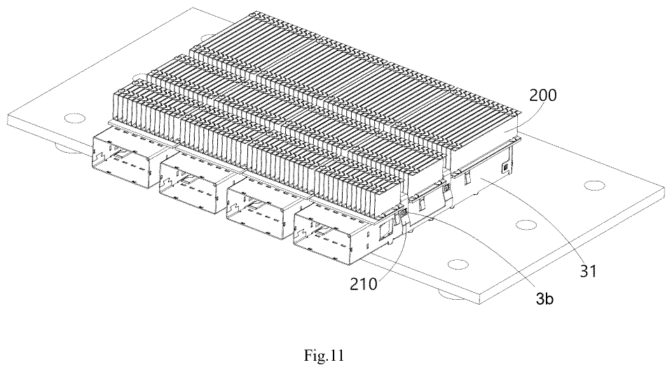

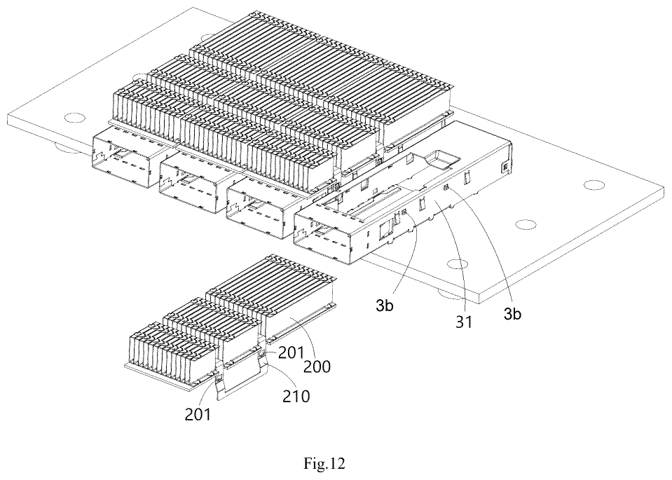

As shown in FIGS. 11 and 12, in the illustrated embodiment, the pair of side walls 31 of the shielding shell 3 are respectively formed with locking protrusions 3b suitable for engaging with slot holes 201 in an elastic clip 210 of an air-cooling heat sink 200, so that the air-cooling heat sink 200 can be installed and locked onto the shielding shell 3.

In an embodiment, locking spring pieces 3a and a locking protrusion 3b are formed on each of a pair of side walls 31 of the shielding shell 3. The locking spring pieces 3a are suitable for engaging with the locking structure 15 on the liquid-cooling plate 10 of the above heat dissipation assembly 100, and the locking protrusions 3b are suitable for engaging with the slot holes 201 on the elastic clip 210 of the air-cooling heat sink 200, so that the shielding shell 3 is not only suitable for the heat dissipation assembly 100, but also for the air-cooling heat sink 200. In this way, the heat dissipation assembly 100 on the shielding shell 3 of the connector can be quickly replaced with the air-cooling heat sink 200 with an elastic clip 210, and the air-cooling heat sink 200 on the shielding shell 3 of the connector can also be quickly replaced with the heat dissipation assembly 100 of the present invention.

In the aforementioned exemplary embodiments according to the present invention, the heat dissipation fins of the air-cooling module are welded to the bottom surface of the liquid-cooling plate of the liquid-cooling module, thereby reducing the thermal resistance between the air-cooling module and the liquid-cooling module and improving the heat dissipation performance.

In addition, according to the aforementioned exemplary embodiments of the present invention, a locking spring piece suitable for engaging with the liquid-cooling module of the heat dissipation assembly and a locking protrusion suitable for engaging with the elastic clip of the air-cooling heat sink are formed on the shielding shell of the connector, so that the shielding shell can not only be applied to the heat dissipation assembly of the present invention, but also to the traditional air-cooling heat sink, expanding the application scope of the shielding shell.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

1. A heat dissipation assembly, comprising:
a liquid-cooling module including a liquid-cooling plate, a bottom surface of the liquid-cooling plate has a locking structure; and
an air-cooling module including a plurality of heat dissipation fins, a top surface of each of the plurality of heat dissipation fins is welded to the bottom surface of the liquid-cooling plate, the locking structure engages a locking spring piece on a side wall of a shielding shell of a connector to lock the heat dissipation assembly to the shielding shell, and when the heat dissipation assembly is locked onto the shielding shell, a bottom of the air-cooling module protrudes into the shielding shell through an opening in a top wall of the shielding shell to make thermal contact with a mating connector inserted into the shielding shell.

2. The heat dissipation assembly according to claim 1, wherein a cooling chamber or cooling passage is formed in the liquid-cooling plate to allow a cooling liquid to flow through, the liquid-cooling plate has a cooling liquid inlet and a cooling liquid outlet communicated with the cooling chamber or cooling passage.

3. The heat dissipation assembly according to claim 1, wherein the liquid-cooling plate includes:
a housing having a cooling chamber or cooling passage accommodating a cooling liquid, and a cooling liquid inlet and a cooling liquid outlet communicated with the cooling chamber or cooling passage; and
a bottom cover covering a bottom of the housing to close a bottom opening of the housing, the locking structure is integrally formed on a bottom surface of the bottom cover.

4. The heat dissipation assembly according to claim 1, wherein the heat dissipation assembly includes a single liquid-cooling module and the air-cooling module is one of a plurality of air-cooling modules, the air-cooling modules are arranged side by side and spaced apart from each other in a transverse direction of the liquid-cooling plate, and when the heat dissipation assembly is locked onto the shielding shell, a plurality of bottoms of the air-cooling modules protrude into a plurality of shielding shells of a plurality of connectors, respectively, to thermally contact a plurality of mating connectors inserted into the shielding shells.

5. The heat dissipation assembly according to claim 4, wherein the locking structure comprises a plurality of columns of locking posts arranged side by side in the transverse direction of the liquid-cooling plate, each column of locking posts has a plurality of locking posts spaced apart in a longitudinal direction of the liquid-cooling plate.

6. The heat dissipation assembly according to claim 5, wherein a snap slot engaging with the locking spring piece on the side wall of the shielding shell is formed on a side of each locking post, adjacent columns of locking posts respectively engage with a pair of side walls of the shielding shell.

7. The heat dissipation assembly according to claim 1, wherein the heat dissipation fins are stacked together, a bottom portion of each of the heat dissipation fins protrudes into the shielding shell to thermally contact with the mating connector.

8. The heat dissipation assembly according to claim 1, wherein the top surfaces of the heat dissipation fins are welded to the bottom surface of the liquid-cooling plate by soldering or ultrasonic welding.

9. The heat dissipation assembly according to claim 1, wherein the liquid-cooling plate has a front side and a rear side that are opposite in a longitudinal direction, the heat dissipation assembly further comprises a limit plate detachably installed on the rear side of the liquid-cooling plate, the limit plate rests against a rear end wall of the shielding shell along the longitudinal direction to restrict the heat dissipation assembly to a predetermined installation position.

10. The heat dissipation assembly according to claim 9, wherein, when the heat dissipation assembly is in the predetermined installation position, the locking structure on the heat dissipation assembly engages with the locking spring piece on the shielding shell to lock the heat dissipation assembly to the shielding shell.

11. The heat dissipation assembly according to claim 10, wherein, when the limit plate is removed from the liquid-cooling plate, the heat dissipation assembly can be moved forward along the longitudinal direction relative to the shielding shell from the predetermined installation position to a disassembly position, and when the heat dissipation assembly is in the disassembly position, the locking structure on the heat dissipation assembly separates from the locking spring piece on the shielding shell, allowing the heat dissipation assembly to be removed from the shielding shell.

12. The heat dissipation assembly according to claim 10, wherein a positioning groove is formed on the rear side of the liquid-cooling plate, and an upper part of the limit plate is positioned in the positioning groove and detachably fastened to the rear side of the liquid-cooling plate.

13. A connector assembly, comprising:
a connector, including:
a shielding shell having a top wall and a bottom wall that are opposite in a height direction, a front port and a rear wall that are opposite in a longitudinal direction, and a pair of side walls that are opposite in a transverse direction, an opening is formed in the top wall of the shielding shell, a plurality of locking spring pieces are respectively formed on the pair of side walls of the shielding shell; and
a heat dissipation assembly installed on a top of the shielding shell, the heat dissipation assembly includes a liquid-cooling module having a liquid-cooling plate, a bottom surface of the liquid-cooling plate has a locking structure, and an air-cooling module including a plurality of heat dissipation fins, a top surface of each of the plurality of heat dissipation fins is welded to the bottom surface of the liquid-cooling plate, a bottom of the air-cooling module protrudes into the shielding shell through the opening in the top wall to make thermal contact with a mating connector inserted into the shielding shell, the locking spring pieces engage with the locking structure on the liquid-cooling plate to lock the heat dissipation assembly to the shielding shell.

14. The connector assembly according to claim 13, wherein the heat dissipation assembly includes a single liquid-cooling module and the air-cooling module is one of a plurality of air-cooling modules, the air-cooling modules are arranged side by side and spaced apart from each other in a transverse direction of the liquid-cooling plate, and when the heat dissipation assembly is locked onto the shielding shell, a plurality of bottoms of the air-cooling modules protrude into a plurality of shielding shells of a plurality of connectors, respectively, to thermally contact a plurality of mating connectors inserted into the shielding shells.

15. The connector assembly according to claim 13, wherein a plurality of plug pins are formed on a pair of lower sides of the pair of side walls of the shielding shell.

16. The connector assembly according to claim 15, further comprising a circuit board having a plurality of holes, the plug pins are press fit into the holes in the circuit board to fix the shielding shell to the circuit board.

17. The connector assembly according to claim 16, wherein the connector includes a terminal holder installed in the shielding shell and a terminal held in the terminal holder, a first end of the terminal is in electrical contact with a mating terminal of the mating connector inserted from the front port of the shielding shell, and a second end of the terminal is exposed from a bottom of the shielding shell for electrical connection to the circuit board.

18. The connector assembly according to claim 13, wherein a plurality of locking protrusions are disposed on the pair of side walls of the shielding shell, the locking protrusions engage with a plurality of slot holes in an elastic clip of an air-cooling heat sink to install and lock the air-cooling heat sink onto the shielding shell.

19. A shielding shell, comprising:
a locking spring piece engaging with a locking structure on a liquid cooling plate of a heat dissipation assembly; and
a locking protrusion engaging with a slot hole in an elastic clip of an air-cooling heat sink, the locking spring piece and the locking protrusion are formed on each of a pair of side walls of the shielding shell, the shielding shell is interchangeably usable with the heat dissipation assembly and the air-cooling heat sink.
